(19) United States
(12) Patent Application Publication
(10) Pub. No.: US 2026/0090335 A1
(43) Pub. Date: Mar. 26, 2026

(54) METHODS FOR DETERMINING A TEMPERATURE ACHIEVED BY A HEATING PROCESS

(71) Applicant: Tokyo Electron Limited, Tokyo (JP)

(72) Inventors: Panupong Jaipan, Albany, NY (US); Joshua Peck, Albany, NY (US); Kandabara Tapily, Albany, NY (US); Tek Po Rinus Lee, Albany, NY (US); Ilseok Son, Albany, NY (US); Jungrae Park, Albany, NY (US)

(21) Appl. No.: 19/290,042

(22) Filed: Aug. 4, 2025

Related U.S. Application Data
(60) Provisional application No. 63/698,900, filed on Sep. 25, 2024.

(51) Int. Cl. H01L 21/66; G01N 23/20; H01L 21/268

(52) U.S. Cl. CPC H10P 74/203; G01N 23/20; H10P 34/42

(57) ABSTRACT

A method for determining a temperature achieved on a substrate by a heating process includes receiving the substrate including a metal containing layer disposed over a first layer, the metal containing layer including a metal, the first layer including a first material different from the metal containing layer, and performing the heating process to heat the substrate using a pulsed laser. The method further includes, after performing the heating process, determining a phase composition of the metal containing layer and a material composition of the metal containing layer using a diffraction technique. And the method further includes, using the phase composition and the material composition of the metal containing layer, determining the temperature of the substrate achieved by the heating process.

### CROSS-REFERENCE TO RELATED APPLICATIONS

This application claims the benefit of U.S. Provisional Application No. 63/698,900, filed on Sep. 25, 2024, which application is hereby incorporated herein by reference. This application is related to U.S. Non-Provisional Application Pub. No. US 2025/0054904 A1, published on Feb. 13, 2025, and U.S. Non-Provisional Application Pub. No. US 2025/0079166 A1, published on Mar. 6, 2025, which contents of the applications are hereby incorporated herein by reference.

### TECHNICAL FIELD

The present invention relates generally to a system and method for semiconductor manufacturing, and, in particular embodiments, to a system and method for determining a temperature achieved on a substrate by a heating process.

### BACKGROUND

In semiconductor manufacturing, laser processes are widely utilized for various applications including wafer bonding, layer transfer, and device fabrication. Particularly, rapid-pulsed laser processes have become increasingly prevalent for advanced semiconductor fabrication. However, these rapid laser processes generate localized heat that can potentially damage sensitive semiconductor devices if not properly controlled. Therefore, there exists a desire for a simplified, quantitative method to detect and measure the heat generated during rapid laser-pulsed processes over localized areas of a substrate with sufficient sensitivity to protect advanced semiconductor devices from thermal damage.

### SUMMARY

In accordance with an embodiment of this disclosure, a method for determining a temperature achieved on a substrate by a heating process includes receiving the substrate including a metal containing layer disposed over a first layer, the metal containing layer including a metal, the first layer including a first material different from the metal containing layer, and performing the heating process to heat the substrate using a pulsed laser. The method further includes, after performing the heating process, determining a phase composition of the metal containing layer and a material composition of the metal containing layer using a diffraction technique. And the method further includes, using the phase composition and the material composition of the metal containing layer, determining the temperature of the substrate achieved by the heating process.

In accordance with another embodiment of this disclosure, a method for characterizing a test material on a bonded wafer includes receiving the bonded wafer, the bonded wafer including a plurality of layers disposed between a first wafer and a second wafer, where the plurality of layers includes a metal containing layer including the test material, the test material being in a first composition, and exposing the first wafer to a laser heating process to debond the first wafer from the second wafer. The method further includes, using a characterization technique, determining whether the test material includes characteristics related to the first composition, characteristics related to a second composition different from the first composition, or characteristics related to a third composition different from the first composition and the second composition. And the method further includes using the characteristics determined for the test material, determining, estimating, or deriving a temperature achieved on the second wafer by the laser heating process.

And in accordance with yet another embodiment of this disclosure, a method for characterizing a test material on a substrate includes receiving the substrate including a plurality of layers, where at least one layer of the plurality of layers includes the test material, the test material being in a first composition, and heating the substrate using a pulsed laser. The method further includes determining whether the heating modified the test material such that the test material includes a second composition different from the first composition using a diffraction technique, and after determining whether the heating modified the test material, determining a temperature achieved on the substrate by the heating.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1D illustrate a substrate during various steps of a method for determining a temperature achieved by a heating process on the substrate in accordance with an embodiment of this disclosure;

FIGS. 2A-2B are plots illustrating counts for various scattering angles determined using an X-Ray Diffraction (XRD) technique in accordance with an embodiment of this disclosure;

FIG. 3 illustrates plots comparing counts for various scattering angles determined using an XRD technique, where each plot illustrates an XRD pattern associated with a temperature range comprising the temperature achieved by the heating process on the substrate in accordance with an embodiment of this disclosure;

FIG. 4 is a flowchart of a method for determining a temperature achieved by a heating process on the substrate in accordance with an embodiment of this disclosure;

FIGS. 5A-5D illustrate a bonded wafer during various steps of a method for characterizing a test material on the bonded wafer in accordance with an embodiment of this disclosure;

FIG. 6 is a system diagram of a processing system capable of implementing the method for characterizing a test material and method for determining a temperature achieved by a heating process on the substrate in accordance with an embodiment of this disclosure;

FIG. 7 is a flowchart of a method for determining a temperature achieved by a heating process on the substrate in accordance with an embodiment of this disclosure;

FIG. 8 is a flowchart of a method for characterizing a test material on a bonded wafer in accordance with an embodiment of this disclosure; and

FIG. 9 is a flowchart of a method for characterizing a test material on a substrate in accordance with an embodiment of this disclosure.

### DETAILED DESCRIPTION OF ILLUSTRATIVE EMBODIMENTS

The semiconductor industry currently lacks quantitative thermal indicator methods capable of detecting heat/temperature from rapid pulsed laser processes on localized spots. Conventional approaches that examine melting damage on post-laser processed materials lack the sensitivity for advanced semiconductor devices like NANDs and Logic chips. A challenge of rapid pulsed laser processes is ensuring heat exposure remains below 600° C. to prevent laser-induced thermal damage on device wafers. Without accurate temperature measurement capabilities, optimizing laser process recipes and engineered release layer stacks becomes challenging.

This disclosure provides a simplified quantitative approach to estimate a temperature range comprising a temperature achieved on a substrate by a heating process by utilizing phase characterization techniques such as X-Ray Diffraction (XRD) analysis to identify phase transformations in a test material. This thermal indicator method may be used to create reference samples through RTA at different temperatures, establishing clear phase change markers which may be used to indicate temperature ranges comprising the temperature achieved on the substrate. In embodiments where the test material comprises a metal such as titanium, phase change markers may be established for titanium silicide (TiSi₂) and titanium oxide (TiO₂) where TiSi₂ (C49) formation indicates temperatures above 500° C. but below 700° C., while TiSi₂ (C54) phase presence confirms temperatures exceeding 700° C., and where TiO₂ formation indicates temperatures above 400° C. but below 500° C. The method delivers quick information turnaround (such as less than one week) and offers localized thermal detection sensitivity over specific areas of a substrate, enabling engineers to determine whether nanosecond laser processes maintain temperatures below a desired threshold for device wafer protection, such as 600° C. By implementing this thermal detection approach, manufacturers can effectively optimize rapid laser process recipes and engineered release layer film stacks to prevent heat-induced damage on sensitive semiconductor devices.

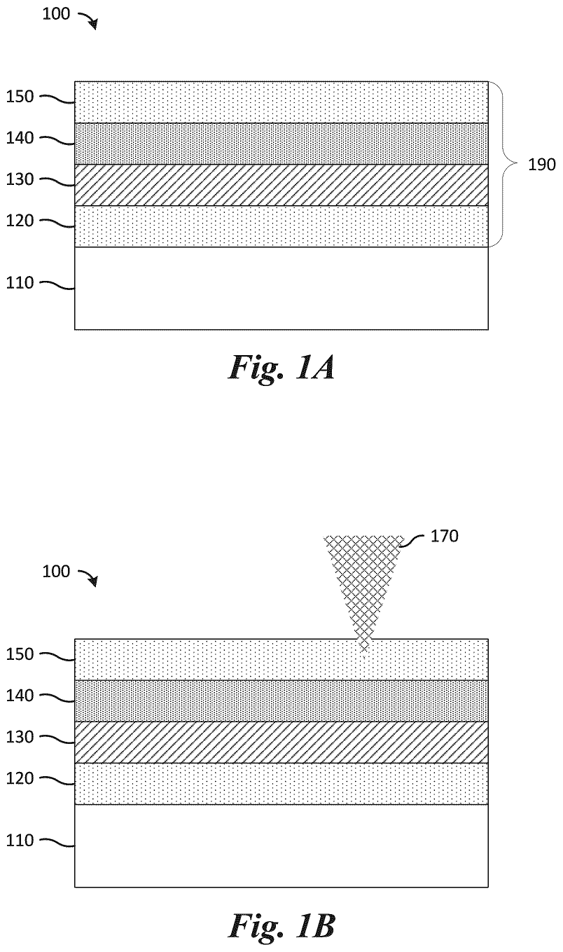

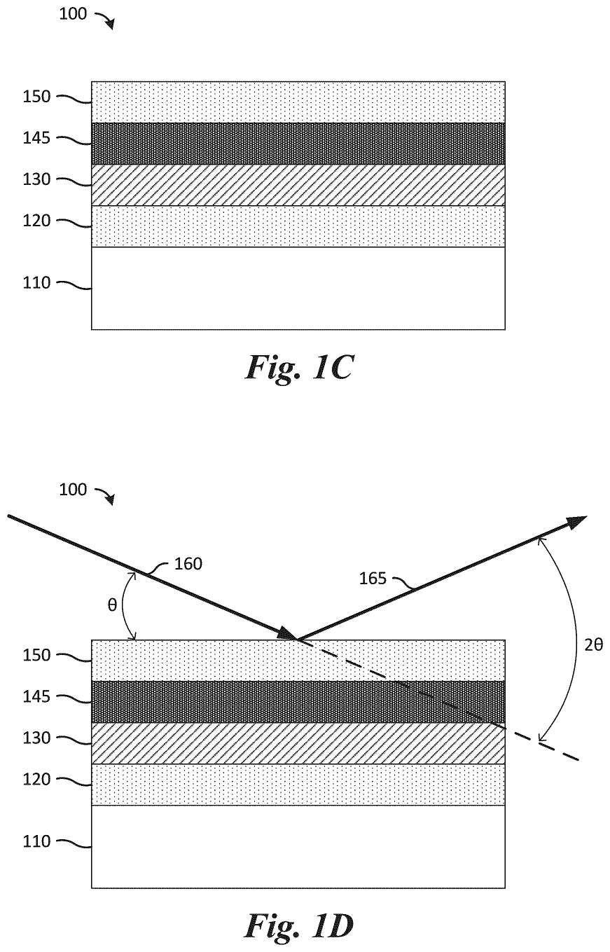

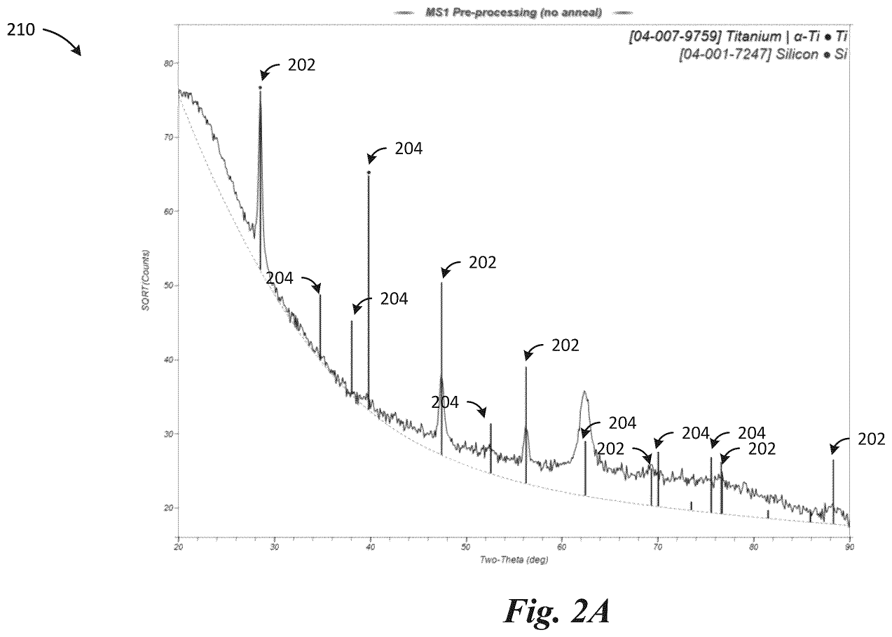

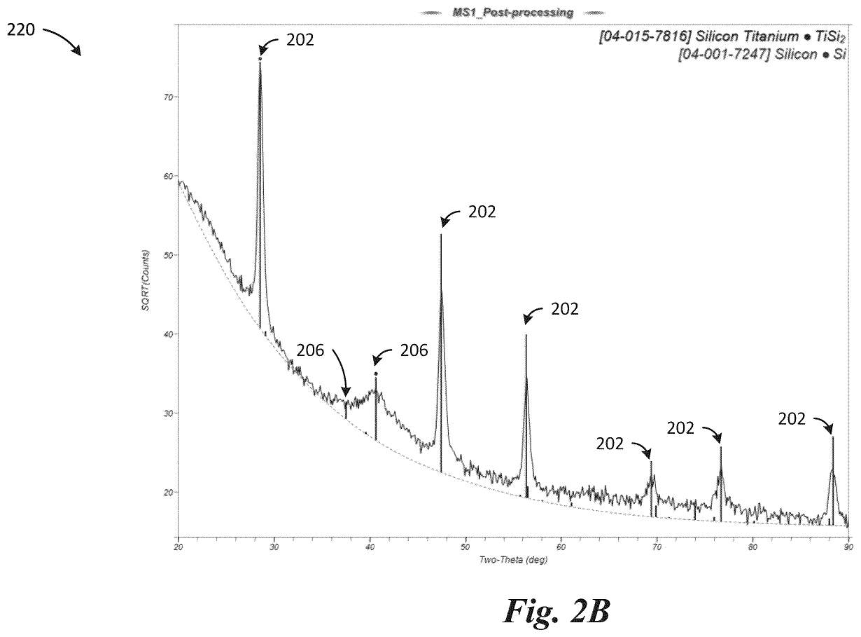

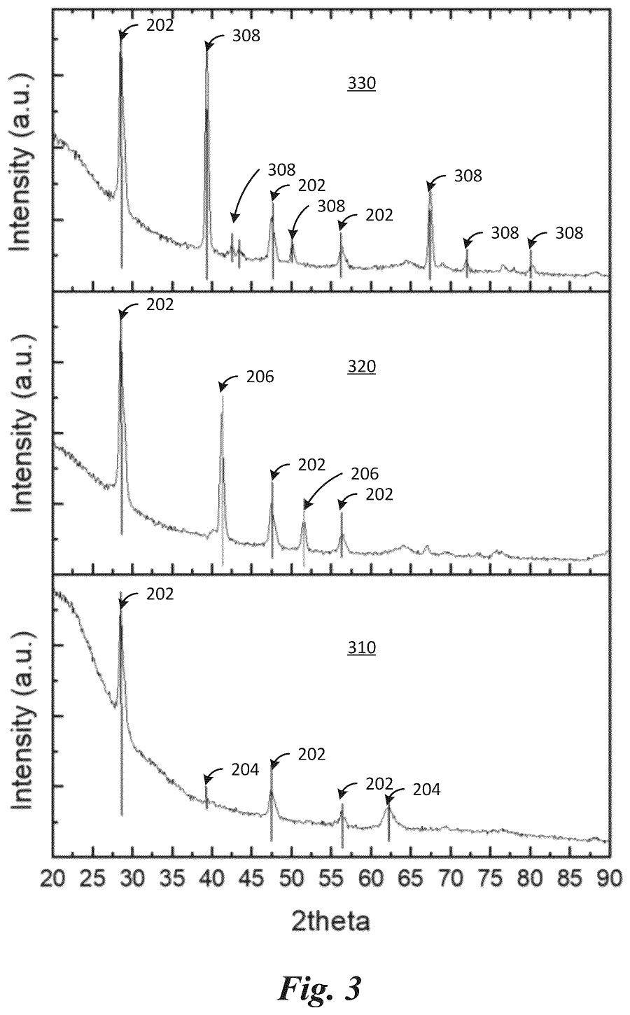

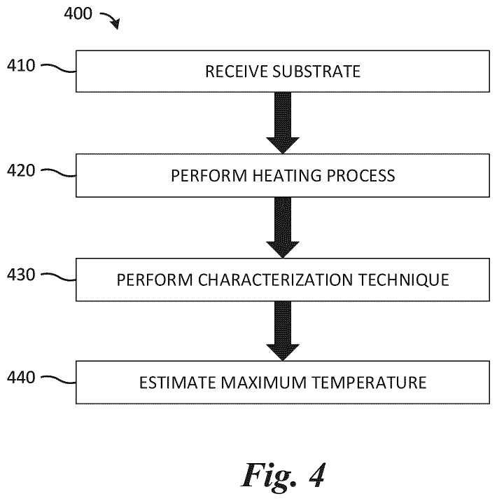

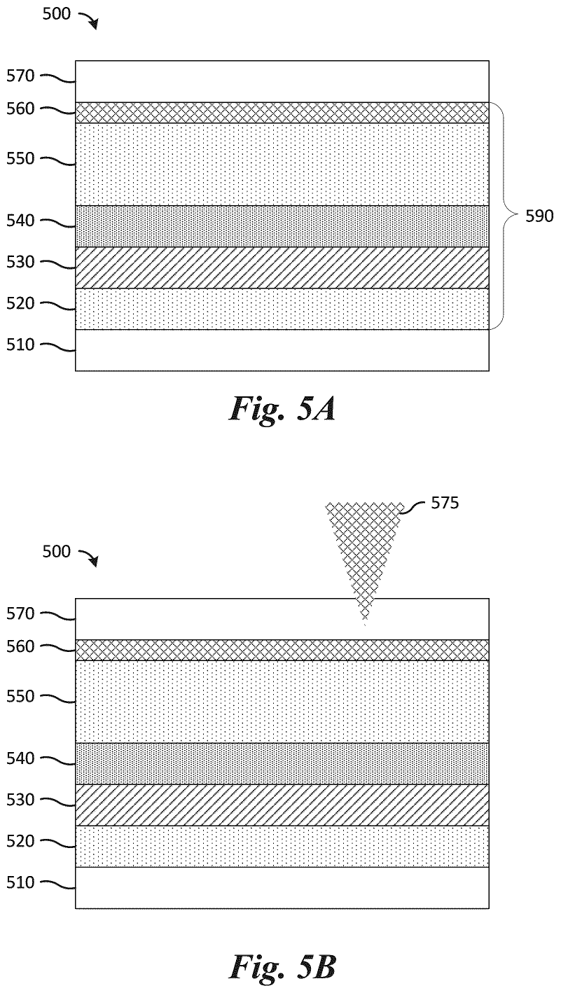

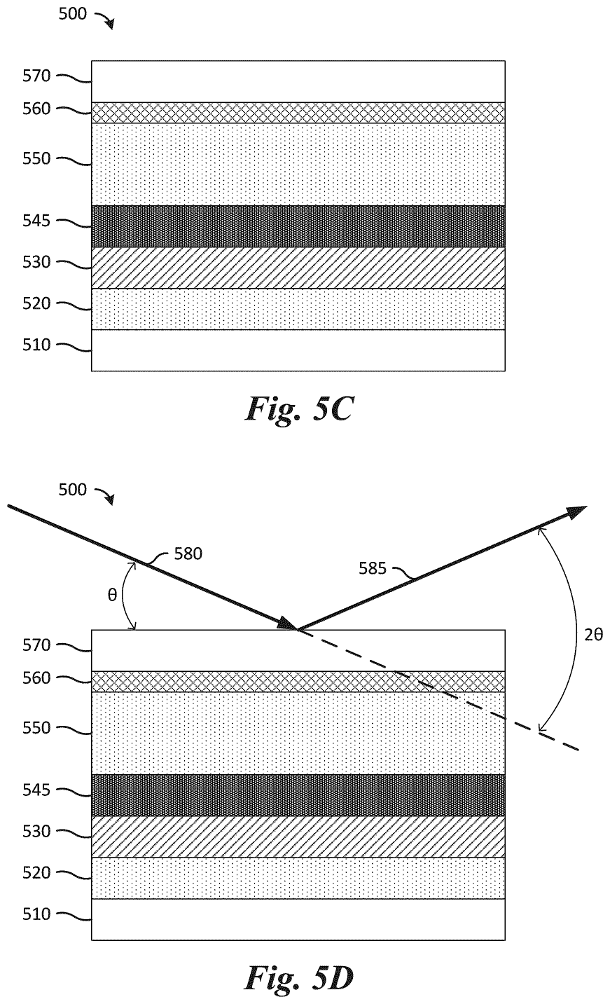

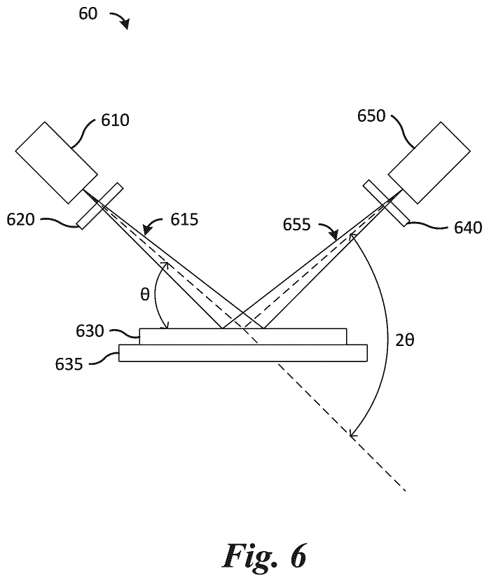

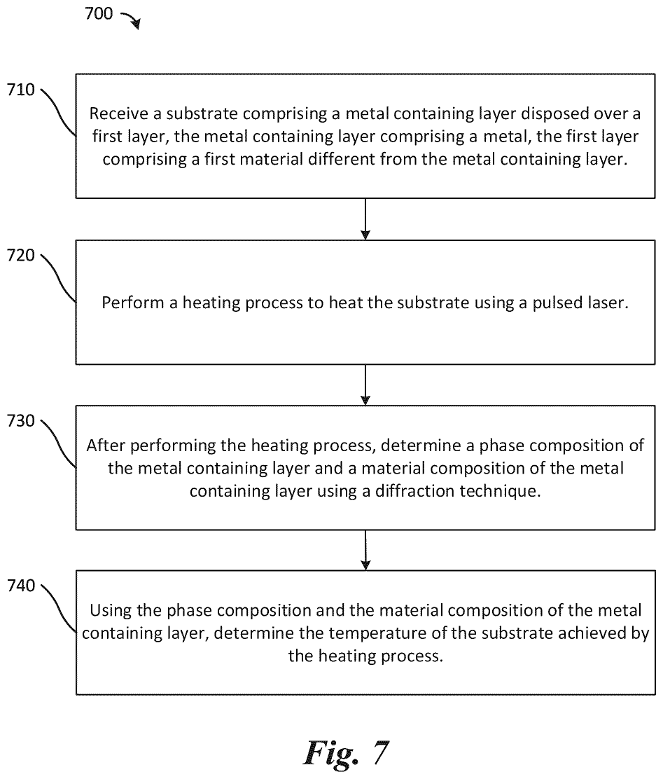

Embodiments provided below describe various methods, apparatuses and systems for determining a temperature achieved on a substrate by a heating process, and in particular, to methods, apparatuses, and systems that use an X-Ray Diffraction (XRD) technique to determine a phase and material composition of a metal containing layer to determine a temperature achieved on the substrate by the heating process. The following description describes the embodiments. FIGS. 1A-1D describe an example method for determining a temperature achieved on a substrate by a heating process. FIGS. 2A-2B illustrate XRD patterns from substrates after performing a heating process with different process parameters, where the XRD patterns indicate different compositions of a metal containing layer on the substrate. FIG. 3 compares three XRD patterns determined from substrates prepared using different parametrizations of the heating process, where the three XRD patterns illustrate different material and phase compositions of the metal containing layer which indicate different thermal thresholds were achieved on each substrate. FIG. 4 is a flowchart used to describe the method of determining a temperature achieved on a substrate by a heating process of this disclosure. FIGS. 5A-5D describe an example method for determining a temperature achieved on a bonded wafer by a heating process. An example processing system capable of implementing the XRD characterization technique of the method of this disclosure is described using FIG. 6. And the flowcharts of FIGS. 7-9 illustrate three other example methods for determining a temperature achieved on a substrate by a heating process in accordance with embodiments of this disclosure.

FIGS. 1A-1D illustrate cross-sectional views of a substrate 100 during various steps of a method for determining a temperature achieved by a heating process on the substrate 100 in accordance with embodiments of this disclosure.

FIG. 1A illustrates a cross-sectional view of the substrate 100 comprising a plurality of layers 190 disposed over a substrate base 110. In various embodiments, the step illustrated in FIG. 1A may be the first step of the method for determining a temperature achieved by a heating process on the substrate 100. For example, the substrate 100 may be received after performing various processing steps to form the plurality of layers 190 over the substrate base 110.

In one or more embodiments, the substrate base 110 may be a silicon wafer, or a silicon-on-insulator (SOI) wafer. In certain embodiments, the substrate base 110 may comprise a silicon germanium wafer, silicon carbide wafer, gallium arsenide wafer, gallium nitride wafer and other compound semiconductors. In other embodiments, the substrate base 110 comprises heterogeneous layers such as silicon germanium on silicon, gallium nitride on silicon, silicon carbon on silicon, as well as layers of silicon on a silicon or SOI substrate. In various embodiments, the substrate base 110 may be a component of, or comprise, a semiconductor device (e.g., a transistor), and may have undergone various processing steps following, for example, a conventional process recipe. For example, the substrate 100 may comprise the substrate base 110 in which various device regions are formed.

In various embodiments, the plurality of layers 190 may comprise various metallization layers, dielectric layers, and device layers of a device being fabricated. For example, the plurality of layers 190 may comprise an oxide layer 120, a first layer 130, a metal containing layer 140, and a second layer 150. The first layer 130 comprises a first material, the metal containing layer 140 comprises a test material, and the second layer 150 comprises a second material. Further, the plurality of layers 190 may be formed using a conventional process using suitable deposition, patterning, and etching techniques to form the plurality of layers 190.

The first material of the first layer 130 may comprise poly-silicon (poly-Si). The test material of the metal containing layer 140 may comprise a metal in a first phase and a first composition such as titanium (Ti). In other embodiments, the metal containing layer 140 may comprise a metal in a first phase and a first composition such as hafnium (Hf) and/or zirconium (Zr). The second material of the second layer 150 may comprise an oxide, such as silicon oxide. In certain embodiments, the oxide layer 120 may comprise silicon oxide. In alternate embodiments, the plurality of layers 190 may comprise silicon nitride, silicon oxynitride, or an O/N/O/N layer stack (stacked layers of oxide and nitride). In some embodiments, the substrate 100 may be a bonded wafer and the heating process to be performed on the substrate 100 is a rapid-pulsed laser process for wafer bonding, wafer debonding, or for layer transfer. In one or more embodiments, the metal containing layer 140 may be a thermal detection layer which may be used to ensure thermal energy does not damage temperature sensitive device layers of the substrate 100.

The plurality of layers 190 may be deposited using an appropriate technique such as vapor deposition comprising chemical vapor deposition (CVD), physical vapor deposition (PVD), atomic layer deposition (ALD), as well as other plasma processes such as plasma enhanced CVD (PECVD) and other processes. After receiving the substrate 100, the method may proceed to perform a heating process, such as a debonding process using a high energy infrared (IR) laser to heat a separation layer of a second substrate (not shown) to transfer device layers to the substrate 100.

FIG. 1B illustrates a cross-sectional view of the substrate 100 during a heating process of the method for determining a temperature achieved by the heating process on the substrate 100. The heating process heats 170 the substrate 100 according to the desired heating process, where the heating process exposes the substrate 100 to a source of energy (heat 170). In one or more embodiments, the heating process may be a localized process which scans and heats desired portions of the substrate 100 as may be desired. In various embodiments, the heating process may be performed using laser processing technology, such as an Infrared (IR) or an Ultraviolet (UV) Laser Lift-Off (LLO) process where the substrate 100 is exposed to a localized laser beam which heats 170 a desired layer of the substrate 100, such as a separation layer to transfer device layers. For example, the heating process may be the IR or UV LLO processes described in U.S. patent application Pub. No. US 2025/0054904 A1, published on Feb. 13, 2025, and U.S. patent application Pub. No. US 2025/0079166 A1, published on Mar. 6, 2025.

In one or more embodiments, the heating process may be a rapid-pulsed laser process for wafer bonding, wafer debonding, layer transfer, or other device fabrication processes. In some embodiments, various substrates may be produced, which may be exposed to heating processes comprising different parameters, such as RTAs to form a database of phase characterizations corresponding to different maximum temperature achieved on substrates using heating processes of varying processing parameters. After heating the substrate 100 using the heating process, layers of the substrate 100 may be altered based on a temperature achieved on the substrate 100 by the heating process, such as described using FIG. 1C.

FIG. 1C illustrates a cross-sectional view of the substrate 100 after performing the heating process of the method for determining a temperature achieved by the heating process on the substrate 100. The heating process heated the metal containing layer 140 to form a heated metal containing layer 145.

In various embodiments, depending on the materials of the layers surrounding the heated metal containing layer 145, the temperature achieved on the substrate 100 by the heating process may have altered the test material and a phase composition of the test material. For example, in an embodiment where the test material comprises a metal, the first material of the first layer 130 comprises poly-Si, and the second material of the second layer 150 comprises an oxide, the heated metal containing layer 145 may comprise the test material, or a metal oxide, or a metal silicide in a first phase, a second phase, or a third phase, or more phases depending on the temperature achieved on the substrate 100 by the heating process.

Further, using a characterization technique on the test material of the heated metal containing layer 145, the temperature achieved on the substrate 100 may be estimated based on the material composition and the phase composition, such as described using FIG. 1D.

FIG. 1D illustrates a cross-sectional view of the substrate 100 during a characterization technique of the method for determining a temperature achieved by the heating process on the substrate 100. In the embodiment illustrated in FIG. 1D, the characterization technique is an X-Ray Diffraction (XRD) technique. During the XRD technique, the substrate may be exposed to an incident beam 160 which interacts with the substrate 100 producing a scattering beam 165 at a scattering angle (2θ) from a beam direction of the incident beam 160.

In various embodiments, the incident beam 160 may be generated by an X-Ray source, such as an X-Ray bulb. In those embodiments, the X-Ray source used to produce the incident beam 160 and a light detector used to collect the scattering beam 165 may be rotated through various scattering angles to collect an XRD pattern for various scattering angles, such as between 20° and 90° with a step size of 0.02° and a counting time of 2 seconds per step.

Further, in some embodiments, the XRD pattern may be determined over a controllable area (or localized spot) of the substrate 100, where multiple XRD patterns may be determined over various areas (or localized spots) of the substrate 100 by scanning the substrate 100. In those embodiments, a map of determined temperatures for each of the various areas of the substrate 100 scanned may be determined. As an example, the temperature map formed in those embodiments may be used to detect irregular temperature variations across the substrate 100 from the heating process, which may subsequently be properly ameliorated by modifying a processing recipe of the heating process, such as by changing a laser power, pulse time, exposure time, frequency, or etcetera in a rapid-pulsed laser process.

After collecting the XRD patterns over the surface of the substrate 100, the method may then determine the crystalline structure and phase composition of the heated metal containing layer 145 by performing an XRD analysis of the XRD pattern. In one or more embodiments, the XRD analysis comprises performing a peak finding algorithm on the XRD pattern to determine peaks at various scattering angles (2θ), where the peaks may correspond to different crystalline structures and phase compositions of the material of the heated metal containing layer 145. In various embodiments, the crystalline structure, the material composition, and the phase composition determined using the XRD patterns may then be used to determine a temperature range that encompasses the temperature achieved on the substrate 100 by the heating process, where the determined temperature range estimates the temperature achieved on the substrate 100 by the heating process.

In the XRD characterization technique, an X-ray source directs the incident beams 160 toward the substrate 100 at a specific incident angle θ. The X-rays interact with the crystalline structure of the heated metal containing layer 145 and are diffracted according to Bragg's law. The scattering beams 165 are diffracted at a scattering angle (2θ) relative to the incident beam 160 direction and may be detected by an X-ray detector. By measuring the intensity of the scattering beams 165 across a range of 2θ angles, a diffraction pattern characteristic of the crystalline phases in the heated metal containing layer 145 can be obtained.

In various embodiments, the diffraction pattern may reveal specific peaks corresponding to different crystalline phases. For example, if the heated metal containing layer 145 originally comprised titanium that was subjected to heating, the XRD analysis may show peaks corresponding to unreacted titanium, titanium oxide, titanium silicide in the C49 phase, titanium silicide in the C54 phase, or a combination of these phases depending on the temperature achieved by the heating process.

The presence of specific phases can be correlated with temperature ranges based on known phase transformation temperatures. For instance, the formation of titanium silicide in the C49 phase indicates that the temperature reached at least 500° C., while the presence of the C54 phase suggests that the temperature exceeded 700° C. If only unreacted titanium is detected, this indicates that the temperature remained below 500° C. As another example, in an embodiment where the second layer 150 comprises an oxide and only unreacted titanium is detected, this indicates that the temperature remained below 400° C. Further, in an embodiment where the second layer 150 comprises an oxide and the formation of titanium oxide is detected, this suggests that the temperature exceeded 400° C. but remained below 500° C. In those embodiments, the presence of titanium silicide in C49 phase and the presence of titanium silicide in the C54 phase indicate the same as described above.

Though the example above describes embodiments where the metal containing layer 140 comprises titanium, other embodiments may perform similarly for different metals, where various crystallizations and phases of the test material may be used to estimate temperature ranges for the temperature according to metal oxides, metals, and metal silicides formed or remaining on the heated metal containing layer 145 by the heating process.

In various embodiments, the XRD characterization technique may be performed after cooling the substrate 100 after performing the heating process. In one or more embodiments, the XRD characterization technique provides a non-destructive method for analyzing the phase composition of the heated metal containing layer 145. The results of this analysis can be used to estimate the temperature achieved on the substrate 100 by the heating process, which may be used to beneficially optimize rapid thermal processes such as nanosecond laser annealing where conventional temperature measurement techniques may not be applicable due to the short duration and localized nature of the heating. Further, the method described using FIGS. 1A-1D also beneficially enables localized temperature estimation, which may be used to further modify process recipes for rapid thermal processes to prevent damaging the substrate 100. Additionally, the temperature estimation method of this disclosure may be much faster than conventional destructive methods.

In embodiments where the heated metal containing layer 140 was a thermal detection layer, after performing the XRD characterization technique to estimate a temperature range achieved on the heated metal containing layer 140 by the heating process (whether localized or fully exposing the substrate 100 to a thermal energy source), the temperature range may be used to determine whether underlying device layers of the substrate 100 may have been damaged due to the heating process.

FIGS. 2A-2B illustrate X-ray Diffraction (XRD) patterns that serve as reference standards for determining temperature ranges experienced during rapid thermal processes based on phase transformations in a titanium-silicon system. For example, the XRD patterns illustrated in the plots of FIGS. 2A-2B may be the XRD pattern determined using the step described in FIG. 1D in embodiments where the metal containing layer 140 comprises titanium and the first layer 130 comprises poly-Si, and where the characterization technique for the heated metal containing layer 145 uses an XRD technique.

FIG. 2A shows an XRD pattern 210 obtained from a sample that has been subjected to temperatures below 500° C. The diffraction pattern displays characteristic polycrystalline silicon (poly-Si) peaks 202 and titanium (Ti) peaks 204. The poly-Si peaks 202 appear at specific diffraction angles (scattering angles (2θ)) corresponding to the crystalline structure of silicon, while the Ti peaks 204 correspond to the crystalline structure of elemental titanium. The presence of distinct Ti peaks 204 without any silicide formation indicates that the temperature was insufficient to initiate a reaction between the titanium and silicon layers. This XRD pattern serves as a baseline reference for samples that have not experienced temperatures high enough to trigger silicide formation.

FIG. 2B depicts an XRD pattern 220 obtained from a sample that has been subjected to temperatures between 500° C. and 700° C. This diffraction pattern shows poly-Si peaks 202 along with titanium silicide peaks in the C49 crystalline phase 206. The C49 phase has a specific orthorhombic crystal structure that produces characteristic diffraction peaks distinct from both elemental titanium and the C54 phase of titanium silicide. Notably, the XRD pattern 220 does not exhibit any peaks corresponding to the C54 phase of titanium silicide, which would form at temperatures above 700° C.

The absence of Ti peaks 204 in FIG. 2B indicates that the elemental titanium has completely reacted with silicon to form the C49 phase of titanium silicide. Similarly, the absence of peaks corresponding to the C54 phase confirms that the temperature did not exceed 700° C. during the heating process. This specific combination of present and absent peaks provides a clear indication that the temperature reached during the heating process was between 500° C. and 700° C.

In various embodiments, these XRD patterns can be used as reference standards for evaluating samples subjected to heating processes comprising rapid thermal heating, such as nanosecond laser annealing. Comparing the XRD pattern of a process sample with these reference patterns enables an estimate for the temperature achieved by the heating process. And the temperature estimate may be used for optimizing process parameters of the heating process to prevent thermal damage to device structures as desired.

For example, in applications where preventing temperatures above 600° C. is desired to maintain device integrity, the appearance of C49 phase peaks without C54 phase peaks in the XRD pattern would indicate that the process temperature is approaching an upper limit of the acceptable range. Process parameters may then be adjusted to ensure that the temperature remains within desired limits to prevent damaging the substrate (such as device layers of the substrate) while still achieving the desired result of a heating process such as a rapid thermal process.

FIG. 3 illustrates X-ray Diffraction (XRD) patterns for samples processed at different temperature ranges, demonstrating the phase transformations that occur in titanium and silicon materials as temperature increases. FIG. 3 illustrates three distinct plots arranged vertically, each representing a specific temperature range and corresponding phase composition.

A bottom plot 310 displays XRD patterns for samples processed at temperatures below 500° C. In this temperature range, the diffraction pattern shows distinct polycrystalline silicon (poly-Si) peaks 202 and titanium (Ti) peaks 204. The presence of these peaks without any metal silicide formation indicates that the temperature was insufficient to initiate a reaction between the titanium and silicon layers. In this temperature regime, the titanium and silicon layers remain as separate phases with their original crystalline structures intact.

A middle plot 320 represents XRD patterns for samples processed at temperatures between 500° C. and 700° C. This plot shows poly-Si peaks 202 along with titanium silicide peaks in the C49 crystalline phase 206. The appearance of the C49 phase peaks indicates that a solid-state reaction has occurred between the titanium and silicon layers. The C49 phase is characterized by a higher resistivity orthorhombic crystal structure. The presence of both poly-Si peaks and C49 phase peaks suggests that a silicidation reaction has occurred but has not completely transformed all available materials of a metal containing layer.

A top plot 330 shows XRD patterns for samples processed at temperatures above 700° C. In this temperature range, the diffraction pattern exhibits poly-Si peaks 202 and titanium silicide peaks in a C54 crystalline phase 308. The C54 phase peaks 308 represent a more thermodynamically stable form of titanium silicide with lower resistivity compared to the C49 phase peaks 206. The transformation from C49 to C54 phase occurs at temperatures above 700° C. and results in a different crystal structure that can be clearly identified by the characteristic C54 phase peaks 308.

In various embodiments, these distinct XRD patterns can serve as calibrated references for determining the temperature by a heating process on a substrate, such as a rapid thermal process such as nanosecond laser processing. By comparing the XRD pattern of a sample subjected to a laser process with these reference patterns, the temperature range comprising the temperature achieved on the sample by the heating process can be estimated based on the presence of specific phase compositions.

In one or more embodiments, after determining the temperature achieved on the substrate by the heating process using the XRD pattern, the estimated temperature may be used to determine adjustments for the heating process. For example, if the temperature was determined to exceed 600° C., the heating process may be adjusted to reduce the temperature and avoid damaging the substrate.

FIG. 4 illustrates a flowchart of a method 400 for determining the temperature achieved by a heating process on a substrate in accordance with various embodiments of the disclosure. The method 400 provides a systematic approach for quantitatively estimating temperature ranges comprising the temperature achieved on the substrate by the heating process, and may be particularly useful for those with extremely short durations such as nanosecond laser processing using a pulsed laser.

The method 400 begins at step 410 with receiving a substrate. In various embodiments, the substrate may comprise multiple layers, with at least one layer comprising a test material that undergoes phase transformations at specific temperature thresholds. For example, the substrate may comprise a silicon wafer with a silicon oxide layer, a polycrystalline silicon layer, and a titanium metal containing layer. The test material is selected based on well-characterized phase transformation behavior at temperatures relevant to the process being evaluated. In an embodiment, step 410 may be as described for the step illustrated in FIG. 1A.

At step 420, the method 400 continues with heating the substrate using a specific heating process. In one or more embodiments, the heating process may comprise a rapid-pulsed laser process, such as a nanosecond laser process used in semiconductor manufacturing, or a Laser Lift-Off (LLO) process. The heating process may be performed using various parameters comprising different laser energies, pulse frequencies, and scan patterns. During this heating step, the test material may undergo phase transformations depending on the temperature reached. For example, titanium in contact with silicon may transform into titanium silicide in the C49 phase if the temperature exceeds 500° C., or further transform into the C54 phase if the temperature exceeds 700° C. As another example, titanium in contact with an oxide may transform into titanium oxide if the temperature exceeds 400° C. In an embodiment, step 420 may be as described for the steps illustrated in FIGS. 1B-1C.

Following the heating process, at step 430, a characterization technique is performed on the heated substrate to analyze the test material. In an embodiment, the characterization technique may be X-ray Diffraction (XRD) analysis (an XRD characterization technique), which can identify the crystalline structure and phase composition of the test material in the metal containing layer. The XRD analysis generates a diffraction pattern (or XRD pattern) that shows characteristic peaks corresponding to specific crystalline phases present in the test material. Other characterization techniques may comprise Raman spectroscopy, electron diffraction, electron microscopy, optical microscopy or other analytical methods capable of identifying material phases. In an embodiment, step 430 may be as described for the step illustrated in FIG. 1D and using the plots of FIGS. 2A-2B and FIG. 3.

And in step 440, the method 400 estimates the temperature achieved by the heating process on the substrate based on the characterization results. This estimation is performed by correlating the identified phases with known phase transformation temperatures. For instance, if XRD analysis of a titanium metal containing layer shows only unreacted titanium, this indicates that the temperature remained below 500° C. If the analysis reveals titanium silicide in the C49 phase but no C54 phase, this suggests that the temperature reached at least 500° C. but remained below 700° C. The presence of the C54 phase indicates that the temperature exceeded 700° C. If the analysis reveals titanium oxide without titanium silicide, this suggests the temperature reached at least 400° C. without exceeding 500° C. Other embodiments may use other samples (RTAs) comprising metal containing layers surrounded by a first layer and a second layer of different materials that enable additional temperature range resolution for determining the temperature reached through additional possible phase changes, which may further segment the plots of FIG. 3, as an example.

In various embodiments, the method 400 provides a quantitative approach for determining temperature ranges in processes where conventional temperature measurement techniques may not be applicable. The method 400 can be particularly beneficial by enabling the optimization of rapid pulsed-laser heating processes used in semiconductor manufacturing, where preventing thermal damage to device structures is desired. By understanding the temperature reached by a heating process, parameters can be adjusted to ensure that temperature-sensitive components are not exposed to excessive heat while still achieving the desired process outcomes of the heating process.

FIGS. 5A-5D illustrate cross-sectional views of a bonded wafer 500 during various steps of a method for characterizing a test material on the bonded wafer 500. The method for characterizing a test material on the bonded wafer 500 may begin by receiving the bonded wafer 500 as illustrated in FIG. 5A. The various steps of the method on the bonded wafer 500 illustrated in FIGS. 5A-5D are substantially like the steps of the method described using FIGS. 1A-1D on the substrate 100. And layers of the bonded wafer 500 similarly labeled but offset to a 500 may be as similarly described for layers of the substrate 100 in FIGS. 1A-1D in multiple embodiments.

FIG. 5A illustrates a cross-sectional view of the bonded wafer 500 as received for performing the method for characterizing a test material on the bonded wafer 500. The bonded wafer 500 comprises a first wafer 510 bonded to a second wafer 570 with a plurality of layers 590 disposed between the first wafer 510 and the second wafer 570.

The bonded wafer 500 may comprise any two or more semiconductor elements (such as integrated device dies, wafers, or etcetera) bonded to one another to form the bonded wafer 500. For example, in various embodiments, the first wafer 510 and the second wafer 570 may both be silicon wafers which have been patterned and bonded to form the bonded wafer 500. The bonded wafer 500 may be any wafers bonded through conventional wafer bonding methods, such as direct bonding, surface activated bonding, plasma activated bonding, anodic bonding, adhesive bonding, thermocompression bonding, reactive bonding, or etcetera. For example, the bonded wafer 500 may comprise the first wafer 510 and the second wafer 570 bonded together with an adhesive in various embodiments. In other embodiments, the first wafer 510 and the second wafer 570 may be directly bonded to one another without an adhesive. Similarly, the first wafer 510 and the second wafer 570 may be any of the many types of semiconductor wafer (silicon, silicon-on-insulator, germanium, gallium arsenide, or etcetera).

The plurality of layers 590 comprises an oxide layer 520 formed on the first wafer 510, a first layer 530 formed on the oxide layer 520, a metal containing layer 540 comprising a metal material (such as titanium, hafnium, zirconium, and hafnium zirconium) deposited on the first layer 530, and a second layer 550 comprising a second material formed on the metal containing layer 540. In an embodiment, the bonded wafer 500 may comprise an optional release layer 560 positioned between the second layer 550 and the second wafer 570 to facilitate subsequent separation if desired.

FIG. 5B depicts the bonded wafer 500 during exposure to a heating process. In various embodiments, the heating process may comprise a rapid laser-pulsed process using a pulsed laser, such as a nanosecond laser process or a Laser Lift-Off (LLO) process. A source of energy 575 is directed toward the bonded wafer 500, causing localized heating of the structure. The heating process may be performed using various parameters including different laser energies, pulse frequencies, and scan patterns depending on the specific application.

FIG. 5C illustrates the bonded wafer 500 after completion of the heating process. The heating process modified the metal containing layer 540 into a heated metal containing layer 545. Depending on the temperature reached during the heating process, the heated metal containing layer 545 may undergo phase transformations (crystallinity modifications). For example, if the temperature exceeded 500° C. but remained below 700° C., titanium in the metal containing layer 540 may have reacted with the adjacent polycrystalline silicon to form titanium silicide in the C49 crystalline phase. As another example, if the temperature exceeded 700° C., the titanium silicide may have further transformed into the C54 crystalline phase. And as another example, if the temperature exceeded 400° C. but remained below 500° C., titanium in the metal containing layer 540 may have reacted with adjacent oxide to form titanium oxide.

FIG. 5D shows the bonded wafer 500 being subjected to an X-ray Diffraction (XRD) characterization technique. An X-ray source directs X-rays 580 at a specific angle (incident angle) θ toward the heated metal containing layer 545 of the bonded wafer 500. A light detector may be positioned to receive the diffracted X-rays (scattering beams 585) at a scattering angle (2θ) according to Bragg's law of diffraction. The resulting diffraction pattern provides information about the crystalline structure and phase composition of the heated metal containing layer 545. In one or more embodiments, the XRD pattern can be analyzed to determine whether the heated metal containing layer 545 contains titanium, titanium oxide, titanium silicide in the C49 phase, titanium silicide in the C54 phase, or a combination of these phases. Based on this analysis, the temperature reached during the heating process can be estimated within specific temperature ranges: below 400° C. if only titanium is present, between 400° C. and 500° C. if titanium oxide is detected, between 500° C. and 700° C. if titanium silicide in the C49 phase is detected, or above 700° C. if titanium silicide in the C54 phase is observed.

In some embodiments, hafnium, zirconium, or hafnium zirconium may be used as the metal of the test material rather than titanium. For example, in those embodiments, hafnium, hafnium silicide, and hafnium oxide may be used; or zirconium, zirconium silicide, and zirconium oxide may be used; or hafnium zirconium, hafnium zirconium silicide, and hafnium zirconium oxide may be used.

In various embodiments, this characterization method provides a quantitative approach for determining a temperature range comprising the temperature achieved on a sample by a heating process where conventional temperature measurement techniques may not be applicable due to the extremely short duration and localized nature of the heating.

FIG. 6 illustrates a schematic diagram of a processing system 60 configured to perform X-Ray Diffraction (XRD) characterization on metal containing layers in accordance with various embodiments of this disclosure. The processing system 60 enables precise analysis of crystalline structures and phase compositions in metal containing layers that have undergone thermal processing.

The processing system 60 comprises an X-ray source 610 positioned to direct an incident X-ray beam 615 through incident optics 620 to illuminate an area of a substrate 630. The X-ray source 610 generates monochromatic X-rays with a specific wavelength suitable for diffraction analysis. In an embodiment, the X-ray source 610 may comprise a copper target that produces Cu Kα radiation with a wavelength of approximately 1.54 Å, although other target materials and corresponding wavelengths may be utilized depending on the specifics of the analysis. The incident optics 620 comprises suitable optics for illuminating the area of the substrate 630 with the incident X-ray beam 615, such as a slit.

A substrate holder 635 may be designed to secure and precisely position the substrate 630 comprising the metal containing layer to be analyzed. The substrate holder 635 can be adjusted to orient the substrate 630 at a specific incident angle θ relative to the incoming X-ray beam. In various embodiments, the substrate holder 635 may have rotation and tilt capabilities to allow for precise alignment of the substrate 630 and to enable different types of XRD scans, such as θ-2θ scans, grazing incidence scans, or pole figure measurements.

A light detector 650 is positioned to capture the diffracted X-rays (scattering beams) 655 at an angle 2θ relative to the incident beam after passing through collection optics 640, in accordance with Bragg's law of diffraction. The light detector 650 measures the intensity of the diffracted X-rays across a range of angles. In one or more embodiments, the light detector 650 may be a position-sensitive detector capable of simultaneously measuring diffraction intensity across a range of angles, or it may be a point detector that moves along the 2θ arc to collect the diffraction pattern. In various embodiments, the collection optics 640 comprise suitable optics for enabling the collection of the diffracted X-rays (scattering beams) 655, such as a slit.

In one or more embodiments, the processing system 60 may further comprise a goniometer (not shown) that controls the precise angular positions of the X-ray source 610, substrate holder 635, and light detector 650. In those embodiments, the goniometer enables accurate measurement of the diffraction angles (scattering angles (2θ)) and can be programmed to perform various scanning patterns as may be desired.

A controller (not shown) may be coupled to the X-ray source 610, the substrate holder 635, and the light detector 650 to coordinate their operation and collect measurement data. The controller may comprise computing hardware and software for controlling the XRD measurement process, processing the collected diffraction data, and analyzing the results to identify crystalline phases present in the metal containing layer of the substrate 630.

In various embodiments, the processing system 60 may also comprise a database containing reference diffraction patterns for various materials and phases. The database may be used to compare measured diffraction patterns with known reference patterns to identify specific crystalline phases present in the metal containing layer. For example, the database may contain reference patterns for titanium, titanium silicide in the C49 phase, and titanium silicide in the C54 phase, allowing for identification of these phases in samples that have undergone thermal processing. In various embodiments, the database may be a suitable memory device.

The processing system 60 enables non-destructive analysis of metal containing layers to determine their phase composition after thermal processing. By identifying specific phases present in the metal containing layer, the processing system 60 can provide valuable information about the temperature reached on a substrate by a heating process. This information can be used to optimize process parameters for applications such as nanosecond laser annealing, where conventional temperature measurement techniques may not be applicable due to the extremely short duration and localized nature of the heating. In various embodiments, the processing system 60 may be used to perform the steps described using FIGS. 1D, and 5D, and may be used to determine XRD patterns which may be compared to a reference pattern stored in the database, such as the plots illustrated in FIGS. 2A-2B, and FIG. 3.

FIGS. 7-9 are flowcharts illustrating embodiment methods for determining a temperature achieved on a substrate by a heating process and methods for characterizing a test material on a substrate in accordance with embodiments of this disclosure. The methods of FIGS. 7-9 may be combined with other methods and performed using suitable systems and apparatuses as described herein. Although shown in a logical order, the arrangement and numbering of the steps of FIGS. 7-9 are not intended to be limiting.

Referring to FIG. 7, step 710 of a method 700 for determining a temperature achieved on a substrate by a heating process receives a substrate comprising a metal containing layer disposed over a first layer, the metal containing layer comprising a metal, the first layer comprising a first material different from the metal containing layer. In step 720, the method 700 performs a heating process to heat the substrate using a pulsed laser. In step 730, after performing the heating process of step 720, the method 700 determines a phase composition of the metal containing layer and a material composition of the metal containing layer using a diffraction technique. And in step 740, using the phase composition and the material composition of the metal containing layer determined in step 730, the method 700 determines the temperature of the substrate achieved by the heating process of step 720. In an embodiment, step 710 may be the step illustrated in FIG. 1A, step 720 may be the step illustrated in FIGS. 1B-1C, and steps 730-740 may be the steps described using FIG. 1D and using the processing system 60 of FIG. 6.

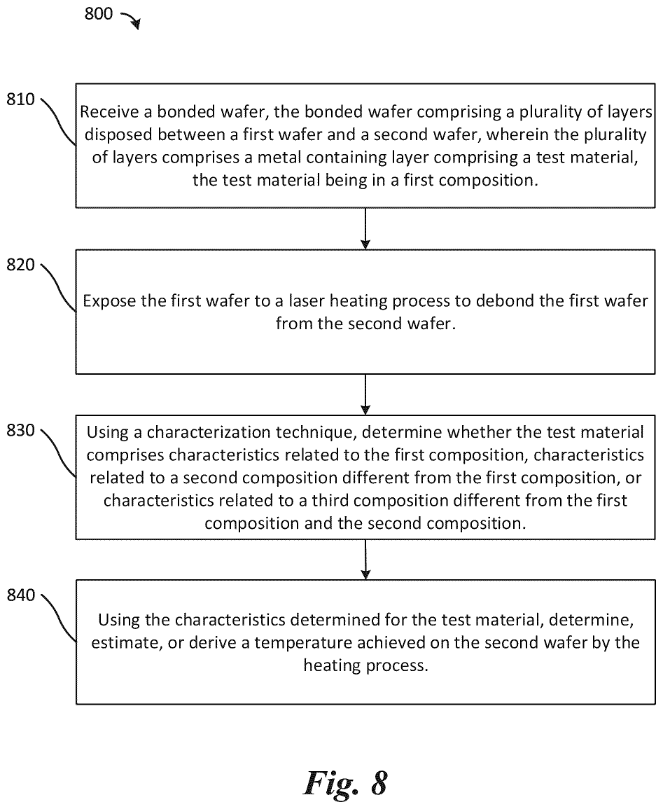

Now referring to FIG. 8, step 810 of a method 800 for characterizing a test material on a bonded wafer receives a bonded wafer, the bonded wafer comprising a plurality of layers disposed between a first wafer and a second wafer, wherein the plurality of layers comprises a metal containing layer comprising a test material, the test material being in a first composition. In step 820, the method 800 exposes the first wafer to a laser heating process to debond the first wafer from the second wafer. In step 830, using a characterization technique, the method 800 determines whether the test material comprises characteristics related to the first composition, characteristics related to a second composition different from the first composition, or characteristics related to a third composition different from the first composition and the second composition. And in step 840, the method 800, using the characteristics determined for the test material in step 830, determines, estimates, or derives a temperature achieved on the second wafer by the heating process. In various embodiments, the method 800 may be the various steps described for the bonded wafer 500 in FIGS. 5A-5D.

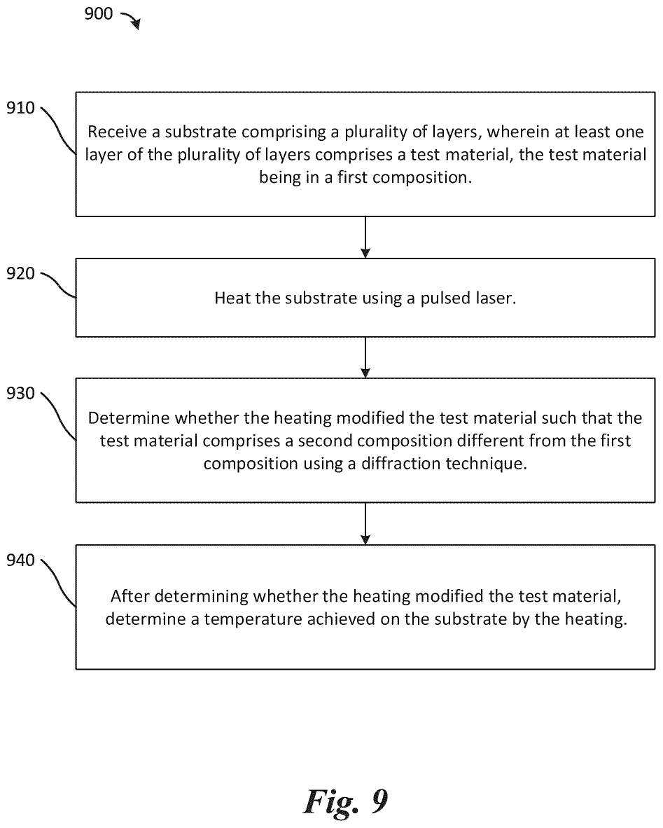

And now referring to FIG. 9, step 910 of a method 900 for characterizing a test material on a substrate receives a substrate comprising a plurality of layers, wherein at least one layer of the plurality of layers comprises a test material, the test material being in a first composition. In step 920, the method 900 heats the substrate using a pulsed laser. In step 930, the method 900 determines whether the heating of step 920 modified the test material such that the test material comprises a second composition different from the first composition using a diffraction technique. And in step 940, the method 900, after determining whether the heating modified the test material, determines a temperature achieved on the substrate by the heating. And the method 900 may be the steps described for either the substrate 100 of FIGS. 1A-1D, or the bonded wafer 500 of FIGS. 5A-5D. Further, the methods 700, 800, and 900 may be embodiments of the method 400 described using FIG. 4.

Example embodiments of the invention are described below. Other embodiments can also be understood from the entirety of the specification as well as the claims filed herein.

Example 1. A method for determining a temperature achieved on a substrate by a heating process includes receiving the substrate including a metal containing layer disposed over a first layer, the metal containing layer including a metal, the first layer including a first material different from the metal containing layer, and performing the heating process to heat the substrate using a pulsed laser. The method further includes, after performing the heating process, determining a phase composition of the metal containing layer and a material composition of the metal containing layer using a diffraction technique. And the method further includes, using the phase composition and the material composition of the metal containing layer, determining the temperature of the substrate achieved by the heating process.

Example 2. The method of example 1, where the diffraction technique includes an X-Ray Diffraction (XRD) technique or an electron diffraction technique, and where the heating process includes an infrared (IR) Laser Lift-Off (LLO) process or an ultraviolet (UV) LLO process.

Example 3. The method of one of examples 1 or 2, where the first material includes poly-silicon, and where determining the temperature of the substrate includes setting the temperature to be less than a first temperature in response to determining the material composition of the metal containing layer does not include a metal silicide, and setting the temperature to be greater than a second temperature in response to detecting a second phase for the metal silicide in the metal containing layer, the second temperature being greater than the first temperature.

Example 4. The method of one of examples 1 to 3, where determining the temperature of the substrate includes setting the temperature to be between the first temperature and the second temperature in response to detecting a first phase for the metal silicide without detecting the second phase, the second phase having a different crystal structure than the first phase for the metal silicide.

Example 5. The method of one of examples 1 to 4, where the metal includes titanium, the metal silicide includes titanium silicide (TiSi2), the first phase includes C49, the second phase includes C54, the first temperature is 500° C., and the second temperature is 700° C.

Example 6. The method of one of examples 1 to 5, where the substrate further includes a second layer disposed over the metal containing layer, the second layer includes oxygen, and the first material includes poly-silicon.

Example 7. The method of one of examples 1 to 6, where determining the temperature of the substrate includes setting the temperature to be less than a first temperature in response to determining the material composition of the metal containing layer does not include a metal oxide, setting the temperature to be between the first temperature and a second temperature in response to determining the material composition of the metal containing layer includes the metal oxide and in response to determining the material composition of the metal containing layer does not include a metal silicide, the second temperature being greater than the first temperature, setting the temperature to be between the second temperature and a third temperature in response to detecting a first phase for the metal silicide without detecting a second phase for the metal silicide in the metal containing layer, the second phase having a different crystal structure than the first phase for the metal silicide, the third temperature being greater than the second temperature, and setting the temperature to be greater than the third temperature in response to detecting the second phase for the metal silicide in the metal containing layer.

Example 8. The method of one of examples 1 to 7, where the second layer is an oxide layer, the metal includes titanium, the metal silicide includes titanium silicide (TiSi2), the metal oxide includes titanium oxide, the first phase includes C49, the second phase includes C54, the first temperature is 400° C., the second temperature is 500° C., and the third temperature is 700° C.

Example 9. A method for characterizing a test material on a bonded wafer includes receiving the bonded wafer, the bonded wafer including a plurality of layers disposed between a first wafer and a second wafer, where the plurality of layers includes a metal containing layer including the test material, the test material being in a first composition, and exposing the first wafer to a laser heating process to debond the first wafer from the second wafer. The method further includes, using a characterization technique, determining whether the test material includes characteristics related to the first composition, characteristics related to a second composition different from the first composition, or characteristics related to a third composition different from the first composition and the second composition. And the method further includes using the characteristics determined for the test material, determining, estimating, or deriving a temperature achieved on the second wafer by the laser heating process.

Example 10. The method of example 9, where the characterization technique includes an X-Ray Diffraction (XRD) technique, an electron diffraction technique, or a microscopy technique, and where the laser heating process includes an infrared (IR) Laser Lift-Off (LLO) process or an ultraviolet (UV) LLO process.

Example 11. The method of one of examples 9 or 10, where the first composition includes a metal, the second composition includes a metal silicide in a first phase, and the third composition includes a metal silicide in a second phase.

Example 12. The method of one of examples 9 to 11, where determining the temperature achieved on the bonded wafer by the laser heating process includes setting the temperature to be less than a first temperature in response to determining the characteristics of the test material include the first composition, setting the temperature to be between the first temperature and a second temperature in response to determining the characteristics of the test material include the second composition, the second temperature being greater than the first temperature, and setting the temperature to be greater than the second temperature in response to determining the characteristics of the test material include the third composition.

Example 13. The method of one of examples 9 to 12, further including, before determining the temperature achieved on the bonded wafer by the laser heating process, determining whether the test material includes characteristics related to a fourth composition different from the first composition, the second composition, and the third composition, where the fourth composition includes a metal oxide.

Example 14. A method for characterizing a test material on a substrate includes receiving the substrate including a plurality of layers, where at least one layer of the plurality of layers includes the test material, the test material being in a first composition, and heating the substrate using a pulsed laser. The method further includes determining whether the heating modified the test material such that the test material includes a second composition different from the first composition using a diffraction technique, and after determining whether the heating modified the test material, determining a temperature achieved on the substrate by the heating.

Example 15. The method of example 14, where the diffraction technique includes an X-Ray Diffraction (XRD) technique or an electron diffraction technique, and where the heating using the pulsed laser includes performing an infrared (IR) Laser Lift-Off (LLO) process, or an ultraviolet (UV) LLO process.

Example 16. The method of one of examples 14 or 15, where determining the temperature achieved on the substrate by the heating includes setting the temperature to be within a temperature range based on whether the test material includes the second composition, and where the second composition includes titanium silicide in a C49 phase, and the temperature range is between 500° C. and 700° C.

Example 17. The method of one of examples 14 to 16, where determining the temperature achieved on the substrate by the heating includes setting the temperature to be within a temperature range based on whether the test material includes the second composition, and where the second composition includes titanium silicide in a C54 phase, and the temperature range is greater than 700° C.

Example 18. The method of one of examples 14 to 17, where determining the temperature achieved on the substrate by the heating includes setting the temperature to be within a temperature range based on whether the test material includes the second composition, and where the second composition includes titanium oxide, and the temperature range is between 400° C. and 500° C.

Example 19. The method of one of examples 14 to 18, where determining the temperature achieved on the substrate by the heating includes setting the temperature to be within a temperature range based on whether the test material includes the second composition, and where the second composition includes hafnium zirconium oxide, and the temperature range is between 400° C. and 500° C.

Example 20. The method of one of examples 14 to 19, further including, based on the temperature achieved on the substrate by the heating, modifying a set of processing parameters of the pulsed laser to either increase or decrease the temperature achieved by heating the substrate as desired, where the set of processing parameters of the pulsed laser includes a laser energy, a pulse frequency, and a scan pattern.

While the inventive aspects are described primarily in the context of nanosecond laser processes for semiconductor device fabrication, it should also be appreciated that these inventive aspects may also apply to other rapid thermal processes in microelectronics manufacturing, materials science, and related fields. In particular, aspects of this disclosure may similarly apply to rapid thermal annealing processes, laser annealing for dopant activation, laser ablation processes, laser-assisted bonding, and other manufacturing processes where precise temperature monitoring of rapid, localized heating is desired.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, embodiments may comprise combinations of embodiments discussed in FIGS. 1-5, and 7-9. It is therefore intended that the appended claims encompass any such modifications or embodiments.

What is claimed is:

1. A method for determining a temperature achieved on a substrate by a heating process, the method comprising:
receiving the substrate comprising a metal containing layer disposed over a first layer, the metal containing layer comprising a metal, the first layer comprising a first material different from the metal containing layer;
performing the heating process to heat the substrate using a pulsed laser;
after performing the heating process, determining a phase composition of the metal containing layer and a material composition of the metal containing layer using a diffraction technique; and
using the phase composition and the material composition of the metal containing layer, determining the temperature of the substrate achieved by the heating process.

2. The method of claim 1, wherein the diffraction technique comprises an X-Ray Diffraction (XRD) technique or an electron diffraction technique, and wherein the heating process comprises an infrared (IR) Laser Lift-Off (LLO) process or an ultraviolet (UV) LLO process.

3. The method of claim 1, wherein the first material comprises poly-silicon, and wherein determining the temperature of the substrate comprises:
setting the temperature to be less than a first temperature in response to determining the material composition of the metal containing layer does not comprise a metal silicide; and
setting the temperature to be greater than a second temperature in response to detecting a second phase for the metal silicide in the metal containing layer, the second temperature being greater than the first temperature.

4. The method of claim 3, wherein determining the temperature of the substrate comprises:
setting the temperature to be between the first temperature and the second temperature in response to detecting a first phase for the metal silicide without detecting the second phase, the second phase having a different crystal structure than the first phase for the metal silicide.

5. The method of claim 4, wherein the metal comprises titanium, the metal silicide comprises titanium silicide (TiSi₂), the first phase comprises C49, the second phase comprises C54, the first temperature is 500° C., and the second temperature is 700° C.

6. The method of claim 1, wherein the substrate further comprises a second layer disposed over the metal containing layer, the second layer comprises oxygen, and the first material comprises poly-silicon.

7. The method of claim 6, wherein determining the temperature of the substrate comprises:
setting the temperature to be less than a first temperature in response to determining the material composition of the metal containing layer does not comprise a metal oxide;
setting the temperature to be between the first temperature and a second temperature in response to determining the material composition of the metal containing layer comprises the metal oxide and in response to determining the material composition of the metal containing layer does not comprise a metal silicide, the second temperature being greater than the first temperature;
setting the temperature to be between the second temperature and a third temperature in response to detecting a first phase for the metal silicide without detecting a second phase for the metal silicide in the metal containing layer, the second phase having a different crystal structure than the first phase for the metal silicide, the third temperature being greater than the second temperature; and
setting the temperature to be greater than the third temperature in response to detecting the second phase for the metal silicide in the metal containing layer.

8. The method of claim 7, wherein the second layer is an oxide layer, the metal comprises titanium, the metal silicide comprises titanium silicide (TiSi₂), the metal oxide comprises titanium oxide, the first phase comprises C49, the second phase comprises C54, the first temperature is 400° C., the second temperature is 500° C., and the third temperature is 700° C.

9. A method for characterizing a test material on a bonded wafer, the method comprising:
receiving the bonded wafer, the bonded wafer comprising a plurality of layers disposed between a first wafer and a second wafer, wherein the plurality of layers comprises a metal containing layer comprising the test material, the test material being in a first composition;
exposing the first wafer to a laser heating process to debond the first wafer from the second wafer;
using a characterization technique, determining whether the test material comprises characteristics related to the first composition, characteristics related to a second composition different from the first composition, or characteristics related to a third composition different from the first composition and the second composition; and
using the characteristics determined for the test material, determining, estimating, or deriving a temperature achieved on the second wafer by the laser heating process.

10. The method of claim 9, wherein the characterization technique comprises an X-Ray Diffraction (XRD) technique, an electron diffraction technique, or a microscopy technique, and wherein the laser heating process comprises an infrared (IR) Laser Lift-Off (LLO) process or an ultraviolet (UV) LLO process.

11. The method of claim 9, wherein the first composition comprises a metal, the second composition comprises a metal silicide in a first phase, and the third composition comprises a metal silicide in a second phase.

12. The method of claim 9, wherein determining the temperature achieved on the bonded wafer by the laser heating process comprises:
setting the temperature to be less than a first temperature in response to determining the characteristics of the test material comprise the first composition;
setting the temperature to be between the first temperature and a second temperature in response to determining the characteristics of the test material comprise the second composition, the second temperature being greater than the first temperature; and
setting the temperature to be greater than the second temperature in response to determining the characteristics of the test material comprise the third composition.

13. The method of claim 9, further comprising, before determining the temperature achieved on the bonded wafer by the laser heating process, determining whether the test material comprises characteristics related to a fourth composition different from the first composition, the second composition, and the third composition, wherein the fourth composition comprises a metal oxide.

14. A method for characterizing a test material on a substrate, the method comprising:
receiving the substrate comprising a plurality of layers, wherein at least one layer of the plurality of layers comprises the test material, the test material being in a first composition;
heating the substrate using a pulsed laser;
determining whether the heating modified the test material such that the test material comprises a second composition different from the first composition using a diffraction technique; and
after determining whether the heating modified the test material, determining a temperature achieved on the substrate by the heating.

15. The method of claim 14, wherein the diffraction technique comprises an X-Ray Diffraction (XRD) technique or an electron diffraction technique, and wherein the heating using the pulsed laser comprises performing an infrared (IR) Laser Lift-Off (LLO) process, or an ultraviolet (UV) LLO process.

16. The method of claim 14, wherein determining the temperature achieved on the substrate by the heating comprises setting the temperature to be within a temperature range based on whether the test material comprises the second composition, and wherein the second composition comprises titanium silicide in a C49 phase, and the temperature range is between 500° C. and 700° C.

17. The method of claim 14, wherein determining the temperature achieved on the substrate by the heating comprises setting the temperature to be within a temperature range based on whether the test material comprises the second composition, and wherein the second composition comprises titanium silicide in a C54 phase, and the temperature range is greater than 700° C.

18. The method of claim 14, wherein determining the temperature achieved on the substrate by the heating comprises setting the temperature to be within a temperature range based on whether the test material comprises the second composition, and wherein the second composition comprises titanium oxide, and the temperature range is between 400° C. and 500° C.

19. The method of claim 14, wherein determining the temperature achieved on the substrate by the heating comprises setting the temperature to be within a temperature range based on whether the test material comprises the second composition, and wherein the second composition comprises hafnium zirconium oxide, and the temperature range is between 400° C. and 500° C.

20. The method of claim 14, further comprising, based on the temperature achieved on the substrate by the heating, modifying a set of processing parameters of the pulsed laser to either increase or decrease the temperature achieved by heating the substrate as desired, wherein the set of processing parameters of the pulsed laser comprises a laser energy, a pulse frequency, and a scan pattern.
